(19) United States
(12) Patent Application Publication
(10) Pub. No.: US 2023/0237215 A1
(43) Pub. Date: Jul. 27, 2023

(54) CONTINGENCY FORECASTING SYSTEM

(71) Applicant: Eaton Intelligent Power Limited, Dublin 4 (IE)

(72) Inventors: Adi BOTEA, Dublin, Ireland, Clonsilla (IE); Catriona CLARKE, Newbridge (IE); Frankie BATES, Dublin, Dublin, 4 (IR)

(21) Appl. No.: 17/999,631

(22) PCT Filed: Dec. 9, 2020
(86) PCT No.: PCT/EP2020/085385

§ 371 Date: Nov. 22, 2022

(30) Foreign Application Priority Data
May 27, 2020 (GB) 2007883.8

(51) Int. Cl. G06F 30/20

(52) U.S. Cl. CPC G06F 30/20

(57) ABSTRACT

A contingency forecasting system for computer generating a contingency forecast simulation of a monitored system to receive a plurality of monitored event records each describing a state of the monitored system during a monitored event of the monitored system having a monitored attribute for each of a plurality of variables. An extraction module extracts one or more of the plurality of monitored event records as exceptions if the monitored values satisfy respective regularity condition. A modification module is configured to generate one or more modified event records. A selection module is configured to select a subset of contingency event records from a set of event records having the extracted exceptional event records and the generated modified event records. A forecast simulation module is configured to apply one or more forecasting techniques to the selected subset of contingency event records to generate contingency forecast simulation parameters.

### TECHNICAL FIELD

The present disclosure relates generally to a contingency forecasting system for generating a contingency forecast simulation of a monitored system. Aspects of the disclosure relate to the contingency forecasting system, to a method of generating a contingency forecast simulation for a monitored system, and to a computer-readable medium.

### BACKGROUND

It is common practice to monitor a system and to record data associated with the state of the system during different scenarios or events.

The recorded data may include an attribute or value for each of a plurality of variables of the monitored system during each event. In this manner, the state of the monitored system may be described by a respective combination of attributes for each event. The recorded data may also include data that is indicative of the impact of that event on the operation of the monitored system, for example including one or more measurements indicative of the performance of the monitored system during each event.

Over time, data may be recorded for the operation of the monitored system in a large range of events and those events, or the attributes of those events, that significantly affect or negatively impact the operation of the system can be identified.

By identifying such events, or combinations of attributes, the system may be refined to mitigate the impact of such events if they reoccur in the future, thereby improving the robustness of the monitored system.

However, an issue with improving the robustness of the system in this manner is that the monitored system is only optimised for historical events, or combinations of attributes. Hence, there is a risk that the monitored system is insufficiently prepared for unprecedented events, or combinations of attributes, which may occur in the future.

It follows from the above that the time taken for the monitored system to encounter a sufficient breadth of events to provide a desired level of robustness can also be unsatisfactorily long.

It is against this background that the disclosure has been devised.

### SUMMARY OF THE DISCLOSURE

According to an aspect of the disclosure there is provided a contingency forecasting system for generating a contingency forecast simulation of a monitored system. The contingency forecasting system comprises one or more computer processors configured to implement: an input module configured to receive a plurality of monitored event records each describing a state of the monitored system during a monitored event of the monitored system, each monitored event record comprising a monitored attribute (or value) for each of a plurality of variables of the monitored system; an extraction module configured to extract one or more of the plurality of monitored event records as exceptional event records in dependence on a determination of whether the monitored values satisfy respective regularity conditions; a modification module configured to generate one or more modified event records, each modified event record being generated by modifying the monitored attribute of at least one of the variables of one of the monitored event records; a selection module configured to select a subset of contingency event records from a set of event records comprising the extracted exceptional event records and the generated modified event records; and, a forecast simulation module configured to apply one or more forecasting techniques to the selected subset of contingency event records to generate one or more output parameters as the contingency forecast simulation.

Advantageously, the contingency forecasting system is configured to generate modified event records that expand the coverage of the contingency forecast simulation to include possible, but not previously encountered, combinations of monitored attributes for the monitored system. Furthermore, the contingency forecasting system is advantageously configured to select the subset of contingency event records, upon which the contingency forecast simulation is based, to balance the breadth of coverage of the contingency forecast simulation, with the computational requirements of generating that simulation.

It is anticipated that the disclosure will enable an increased awareness of exceptional events that could occur and affect the monitored system in the future. Consequently, the contingency forecast simulation may be used to determine how the monitored system would perform during such exceptional events, and to determine appropriate measures to take to improve the robustness of the monitored system in such conditions, for example.

It shall be appreciated that, in the context of events, the use of the term contingency in the following description is intended to mean events that may but are not certain to occur. It follows that the ‘contingency forecast simulation’ may take the form of a predictive computer model of the monitored system when subjected to the subset of contingency events, i.e. a computer modelling of the operation of the monitored system in response to the monitored attributes of each of the contingency events that may but are not certain to occur.

Each of the variables of the monitored system may be measurable, e.g. providing a monitored attribute in the form of a numerical value, and/or categorizable, e.g. providing a monitored attribute in the form of a selected item, which may be associated with a measured attribute. For example, the selected item may be selected from a plurality of items in dependence on one or more measurable attributes.

In an example, the extraction module may be configured to extract the exceptional event records by applying one or more anomaly detection techniques to the monitored attributes of each monitored event record. Such anomaly detection techniques may be configured to identify those monitored event records that include a threshold amount, e.g. at least one, of anomalous attributes.

For example, the one or more anomaly detection techniques may be selected from: an occurrence count of the monitored attributes; and/or cluster analysis of the monitored attributes.

In an example, the modification module may be configured to generate each modified event record by changing the monitored attribute of at least one variable of the respective monitored event record to the monitored attribute of that variable in another one of the monitored event records. Advantageously, this may allow knowledge transfer between monitored event records.

Optionally, the selection module is configured to: estimate one or more risk factors for each event record in the set of event records; and select one or more of the extracted exceptional event records and the modified event records from the set of event records based on the estimated risk factors. Advantageously, such risk factors may be configured to filter the event records that are output to the forecast simulation module based on some prioritised attributes for the event records.

For example, the one or more risk factors may include: a likelihood, or frequency, of occurrence of the monitored attributes of that event record; and/or an impact score that is indicative of the relative impact of the monitored attributes of that event record on the operation of the monitored system. Optionally, the impact score may be a relative impact score. In this manner, the contingency forecasting system is configured to prioritise those monitored event records that are more likely to occur and/or significantly affect the operation of the monitored system.

Optionally, the selection module is configured to select the subset of contingency event records based on a weighted sum of the risk factors for each of the event records in the set of event records. Advantageously, the weighted sum allows a range of risk factors to be combined with the relative weighting indicating the relative importance of such risk factors. In particular, the relative weighting indicating the relative need for the contingency forecast simulation to include those event records associated with a greater risk for those risk factors.

In an example, the selection module is configured to select the subset of contingency event records by comparing the weighted sum of the risk factors of each of the event records in the set of event records to a threshold value.

In another example, the selection module is configured to select the subset of contingency event records by: ranking the set of event records based on the weighted sum of the respective risk factors for each of the event records in the set of event records; determining the cumulative weighted sum of the respective risk factors of the highest ranking event records in the set of event records; and selecting those event records from the set of event records for which the cumulative weighted sum is less than or equal to a threshold value. In this manner, the threshold value may balance the breadth of coverage of the contingency forecast simulation with the computational requirements of determining the contingency forecast simulation.

Optionally, the extraction module is configured to extract one or more of the plurality of monitored event records as exceptional event records that include an anomalous monitored attribute, or more than a threshold amount of anomalous monitored attributes, and to extract one or more of the plurality of monitored event records as regular event records that do not include an anomalous monitored attribute, or that include less than the threshold amount of anomalous monitored attributes. The other monitored attributes of each event record may be considered expected or regular attributes.

In an example, the extraction module may be configured to determine an irregular pattern, for each exceptional event record, by pattern mining the one or more exceptional event records, and/or a regular pattern for each regular event record by pattern mining the one or more regular event records. The modification module may be configured to generate the modified event records in the form of modified patterns, each modified pattern being generated by modifying at least one of the monitored attributes of a respective one of the irregular patterns, or of a respective one of the regular patterns.

Each pattern may be a multi-dimensional graphical structure for a respective one of the monitored event records. The pattern may represent the respective monitored event record with details, such as time or other performance measures, omitted or ignored.

For example, each pattern may comprise one or more of the monitored attributes of the respective event record and a value for a pairwise connection between each pair of monitored attributes in that pattern. In particular, each pattern may include a plurality of vertices connected by edges, or pairwise connections, between each pair of vertices. At each vertex, the pattern may include a monitored attribute of a particular variable of the respective monitored event record and each edge of the pattern may be assigned a weight, or a plurality of weights, to provide a numerical value to the pairwise connection between the monitored attributes of the variables of the monitored system.

In pattern form, the monitored event records provide a particularly effective means of generating modified event records that extend the coverage of the contingency forecast simulation whilst numerically estimating the deviation of the modified event records from the respective monitored event records, as shall become clear in the following description. Advantageously, this means that the coverage may be limited to modified event records corresponding to events that are possible for the monitored system to experience.

Optionally, the extraction module is configured to determine the one or more irregular patterns and/or the one or more regular patterns using one or more pattern mining methods selected from: a frequent pattern mining technique; an Apriori algorithm; and/or an Eclat algorithm.

In an example, the modification module is configured to generate each modified pattern by changing at least one of: a monitored attribute, which is not an anomalous monitored attribute, of a respective regular pattern to an anomalous monitored attribute for that variable in an exceptional event record; and a monitored attribute, which is not an anomalous monitored attribute, of a respective irregular pattern to another monitored attribute for that variable, which is not an anomalous monitored attribute, in a regular event record.

Optionally, the modification module may be configured to output modified patterns to the selection module. Each modified pattern that is output to the selection module may have a weighted sum of pairwise distance to the respective irregular pattern, or the respective regular pattern, that is less than a threshold distance. The weighted sum of pairwise distance to the respective irregular pattern, or the respective regular pattern, may be caused by changing the monitored attribute. The threshold distance may be calculated according to a corresponding metric.

In an example, the modification module is configured to select a set of modified patterns from the generated modified patterns to output to the selection module by: determining a weighted sum of pairwise distances between each modified pattern generated and the respective irregular pattern, or the respective regular pattern; and selecting the modified patterns having a weighted sum of pairwise distances that is less than the threshold distance.

In an example, each exceptional event record in the subset of contingency event records takes the form of a respective one of the irregular patterns and each modified event record in the subset of contingency event records takes the form of a respective one of the modified patterns. The selection module may be configured to select the subset of contingency event records from the one or more irregular patterns and the one or more modified patterns.

According to another aspect of the disclosure there is provided a computer-implemented method of generating a contingency forecast simulation of a monitored system. The method comprises: receiving a plurality of monitored event records each describing a state of the monitored system during a monitored event of the monitored system, each monitored event record comprising a monitored attribute for each of a plurality of variables of the monitored system; extracting one or more of the plurality of monitored event records as exceptional event records in dependence on a determination of whether the monitored values satisfy respective regularity conditions; generating one or more modified event records, each modified event record being generated by modifying the monitored attribute of at least one of the variables of one of the monitored event records; selecting a subset of contingency event records from a set of event records comprising the extracted exceptional event records and the generated modified event records; and, generating one or more output parameters as the contingency forecast simulation by applying one or more forecasting techniques to the selected subset of contingency event records.

According to a further aspect of the disclosure there is provided a non-transitory, computer-readable medium having instructions stored thereon that, when executed by a computer, cause the computer to carry out the method described in a previous aspect of the disclosure.

It will be appreciated that preferred and/or optional features of each aspect of the disclosure may be incorporated alone or in appropriate combination in the other aspects of the disclosure also.

### BRIEF DESCRIPTION OF THE DRAWINGS

Examples of the disclosure will now be described with reference to the accompanying drawings, in which:

FIG. 1 shows a schematic illustration of an example contingency forecasting system in accordance with an embodiment of the disclosure;

FIG. 2 schematically illustrates an example method in accordance with an embodiment of the disclosure of operating the contingency forecasting system shown in FIG. 1;

FIG. 3 schematically illustrates example sub-steps of a step in the method shown in FIG. 2;

FIG. 4 schematically illustrates example sub-steps of another step in the method shown in FIG. 2; and

FIG. 5 schematically illustrates example sub-steps of a further step in the method shown in FIG. 2.

### DETAILED DESCRIPTION

Embodiments of the disclosure relate to a contingency forecasting system for generating a contingency forecast simulation of a monitored system. Such a contingency forecast simulation may be used to produce a risk awareness snapshot for improving the robustness of the monitored system.

Considered in more detail, the contingency forecasting system is configured to receive a data set comprising a plurality of monitored event records that may each describe a state of the monitored system during a respective event, or scenario, during which the system was monitored.

It shall be appreciated that the system may have previously been monitored for a period that includes a plurality of such events, providing such data.

Each monitored event record may comprise a monitored attribute, or value, for each of a plurality of variables of the monitored system. In this manner, each monitored event record may include a combination of attributes that describe the state of the monitored system during that event. Each monitored event record may also include one or more performance measures that are indicative of the performance of the monitored system during that event, thereby indicating the effect of that event on the operation of the monitored system.

The contingency forecasting system is configured to analyse the plurality of monitored event records and to identify, or extract, one or more exceptional event records that include monitored attributes that do not satisfy respective regularity conditions. In other words, the contingency forecasting system may be configured to detect one or more exceptional event records that include at least one anomalous attribute. Such exceptional event records are identified to highlight unusual events that may have had a significant impact on the operation of the system.

The contingency forecast simulation could be based on such exceptional event records alone but, advantageously, the contingency forecasting system is configured to increase the coverage of the contingency forecast simulation by generating one or more modified event records based on the plurality of monitored event records. Each modified event record is generated by modifying at least one of the monitored attributes of a respective monitored event record. For example, the monitored attribute of one variable of a first one of the monitored event records may be changed to the monitored attribute of that variable in a second one of the monitored event records.

In this manner, each modified event record provides a simulated combination of monitored attributes describing the state of the monitored system during a possible, although not previously encountered, event.

To give an example, in application to a monitored system of airports, a first event record may describe the state of a first airport monitored during a first event. The first event record may include a first monitored attribute relating to a variable of the weather at that airport, such as an amount of rainfall, and a second monitored attribute relating to another variable, such as an amount of aircraft arrivals at the first airport during the event.

The contingency forecasting system may identify the first event record as an exceptional event, for example due to an anomalously large amount of rainfall.

Accordingly, the contingency forecasting system may generate a modified event record by changing the second monitored attribute, relating to the number of aircraft arrivals, in the first event record to the number of aircraft arrivals recorded in a second event record. The second event record may describe the state of the first airport during a second event where the amount of rainfall was negligible or the second event record may describe the state of a second airport during a respective event.

Modifying event records in the manner described above, allows knowledge transfer between event records, generating possible, but not previously encountered, combinations of monitored attributes for the monitored system.

The contingency forecasting system is further configured to advantageously balance the breadth of coverage with the computational requirements of generating the contingency forecast simulation, by selecting a subset of contingency event records that includes one or more exceptional event records, and/or one or more modified event records, upon which the contingency forecast simulation is based.

It is anticipated that the disclosure will enable an increased awareness of exceptional events that could occur and affect the monitored system in the future. The contingency forecast simulation may then be used to determine how the monitored system would perform during such exceptional events, and to determine appropriate measures to take to improve the robustness of the monitored system in such conditions, for example.

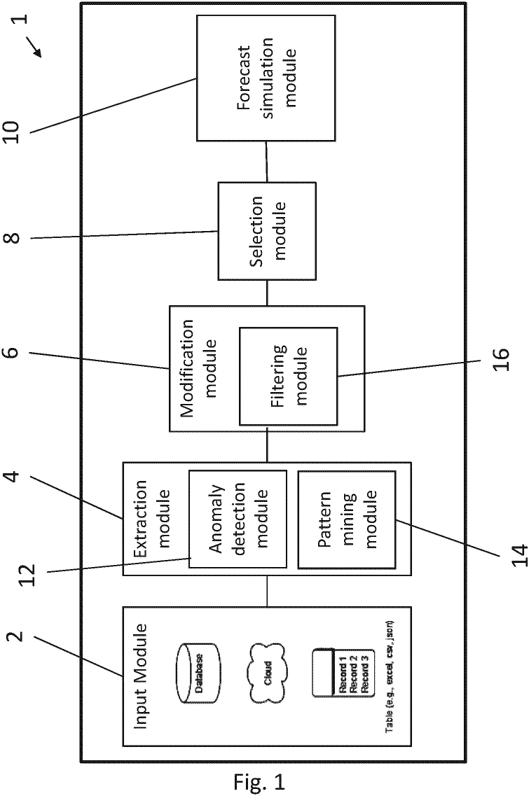

FIG. 1 schematically illustrates an example contingency forecasting system 1 for generating the contingency forecast simulation of a monitored system (not shown).

By way of example only, in the following description the monitored system takes the form of a monitored system of airports that includes a first airport, a second airport and a third airport.

It shall be appreciated that this example is only provided for the sake of clarity and is not intended to be limiting on the scope of the disclosure. Nonetheless, the example system of airports demonstrates that the disclosure is applicable to a system that effectively includes one or more subsystems, such as the first, second and third airports.

In other examples, the monitored system may take any other suitable form, including a monitored vehicle system, such as a particular aircraft, train or automobile, or a monitored system of vehicles such as a fleet of aircrafts. In other further examples, the monitored system may be a system of power distribution or management circuits with variables including loading, voltage and current being recorded amongst other variables. The monitored system may also take the form of a manufacturing facility with variables including the tasks performed, stocks of materials and machines operating being recorded amongst other variables. In another example, the monitored system may take form of a machine within a manufacturing facility with variables such as the inputs and outputs to the machine being monitored amongst other variables.

The contingency forecasting system 1 includes an input module 2, an extraction module 4, a modification module 6, a selection module 8, and a forecast simulation module 10. That is, in the described example five functional elements, units or modules are shown. Each of these units or modules may be provided by suitable software running on any suitable computing substrate using conventional or customer processors and memory. Some or all of the units or modules may use a common computing substrate (for example, they may run on the same server) or separate substrates, or different combinations of the modules may be distributed between multiple computing devices.

The input module 2 is configured to receive and/or store a plurality of monitored event records. Each monitored event record may describe a state of the monitored system during a respective event, or scenario, that the monitored system (or a sub-system of the monitored system in particular) was monitored during, for example.

Each monitored event record comprises a monitored attribute, or value, for each of a plurality of variables of the monitored system. In combination, the plurality of monitored attributes describe the state of the monitored system during that event.

In an example that includes a plurality of sub-systems of the monitored system, the plurality of monitored attributes may include the identification of the subsystem that was monitored during the respective event. For instance, in the described example each event record may include monitored attributes describing the identification of the airport that the monitored event record relates to, i.e. identifying the first, second or third airport, and describing the state of that airport during the event.

Each monitored event record may also include one or more performance measures indicative of the performance of the monitored system during that event. For example, the performance measurements, which may include the time for the monitored system to complete a respective task for example, are comparable to corresponding performance measurements in other monitored event records to indicate the effect of each event, or the combination of monitored attributes, on the operation of the monitored system.

By way of example, a first event record may describe the state of the first airport during a first event, a second event record may describe the state of the first airport during a second event and a third event record may describe the state of the second airport during the first or second event.

Each of the first, second and third event records may comprise a monitored attribute for each of a plurality of variables of the first, second and third airports. The plurality of variables may include the identification of the airport that was monitored, the size of that airport, the location of that airport, a temperature or weather condition at that airport, a time of day at that airport, and/or one or more operations that occurred at that airport, such as the number of aircraft arriving at that airport, the number of aircraft departing from that airport, refuelling, de-icing, and/or technical checks performed on one or more aircraft at that airport, for example.

Each of the first, second and third event records may also comprise one or more performance measurements for the respective airport during that event, such as a duration between aircrafts arriving at, and departing from, the respective airport.

For the purpose of receiving and/or storing such data, the input module 2 may take the form of a memory storage module, such as a cloud storage system or a computer-readable storage medium (e.g., a non-transitory computer-readable storage medium). The computer-readable storage medium may comprise any mechanism for storing information in a form readable by a machine or electronic processors/computational device, including, without limitation: a magnetic storage medium (e.g., floppy diskette); optical storage medium (e.g., CD-ROM); magneto optical storage medium; read only memory (ROM); random access memory (RAM); erasable programmable memory (e.g., EPROM and EEPROM); flash memory; or electrical or other types of medium for storing such information/instructions.

The input module 2 may receive the plurality of monitored event records from any suitable source, including a computing device or one or more sensor systems configured to observe the monitored system, for example.

The extraction module 4 is configured to receive the plurality of monitored event records from the input module 2 and to extract one or more exceptional event records that include one or more monitored attributes not satisfying respective regularity conditions.

For this purpose, the extraction module 4 may further include an anomaly detection module 12. The anomaly detection module 12 may be configured to identify one or more exceptional event records that include a threshold amount of monitored attributes that are considered anomalous, e.g. monitored event records comprising at least one anomalous attribute. The other monitored attributes of the exceptional event record may be considered sufficiently regular, and/or similar, to other monitored attributes, such that they cannot be considered anomalous. Such monitored attributes may be considered expected attributes.

The anomaly detection module 12 may also be configured to identify, or extract, one or more regular event records that include less than the threshold amount of anomalous attributes. For example, each of the regular event records may not include any anomalous attributes and, instead, only include a combination of monitored attributes that are repeated throughout the plurality of monitored event records with sufficient regularity, and/or similarity to other combinations of monitored attributes, such that they cannot be considered anomalous.

As shall become clear, the anomaly detection module 12 may be configured to determine the exceptional event records and/or the regular event records by applying one or more anomaly detection techniques to the monitored attributes of each monitored event record.

It shall be appreciated that the expected attributes and the anomalous attributes may be dependent upon, and therefore be considered in combination with, one or more other monitored attributes, such as an identification of the sub-system of the monitored event record, for example.

To illustrate this further, an exceptional event record in the example system of airports may correspond to abnormal weather conditions, such as unprecedented snowfall, at the first airport and some of the monitored attributes of the exceptional event record may be anomalous attributes, e.g. those monitored attributes indicating the temperature and/or the amount of snowfall.

A first regular event record may correspond to ordinary weather conditions, such as moderate temperature with no rainfall, at the first airport and the monitored attributes may be expected attributes in combination with one another.

However, a second regular event record may correspond to ordinary weather conditions for the second airport and such weather conditions may be distinct from the ordinary weather conditions at the first airport. For example, ordinary weather conditions for the second airport may include some snowfall and the monitored attributes, including a non-zero amount of snowfall for example, of the second regular event record may be expected attributes in combination with one another.

In an example, the extraction module 4 may be advantageously further configured to pattern mine the regular event records and the exceptional event records to identify rules that describe specific patterns within the monitored event records and to determine respective regular and irregular patterns.

For this purpose, the extraction module 4 may also include a pattern mining module 14 configured to determine an irregular pattern for each exceptional event record and a regular pattern for each regular event record. Such patterns may be determined using one or more pattern mining methods, as shall become clear in the following description.

In this manner, the pattern mining module 14 may be configured to output a pattern, or multi-dimensional graphical structure, for each of the monitored event records. The pattern represents the respective monitored event record with details, such as time or other performance measures, omitted to avoid obscuring other information.

For example, each pattern may include a plurality of vertices connected by edges, or pairwise connections, between each pair of vertices. At each vertex, the pattern may include a monitored attribute of a particular variable of the respective monitored event record and each edge of the pattern may be assigned a weight, or a plurality of weights, to provide a numerical value to the pairwise connection between the monitored attributes of the variables of the monitored system.

In this manner, each pattern provides an alternative representation of a respective event record and may provide a representation of a state of the monitored system during a respective event. The irregular patterns include a threshold amount, e.g. one or more, anomalous attributes, whilst the regular patterns largely feature of ordinary, and/or expected, attributes, with less than the threshold amount, or zero, anomalous attributes.

It shall be appreciated that each of the operations described in relation to a pattern in the following description may be equally applicable to the respective event record and vice versa.

In pattern form, the monitored event records provide a particularly effective means of generating modified event records that extend the coverage of the contingency forecast simulation whilst numerically estimating the deviation of the modified event records from the respective monitored event records, as shall become clear in the following description. Advantageously, this means that the coverage may be limited to modified event records corresponding to events that it are possible for the monitored system to experience.

The modification module 6 is configured to generate one or more modified event records based on the plurality of monitored event records. Each of the modified event records is generated by modifying at least one of the monitored attributes of the respective monitored event record.

To transfer knowledge from one event record to another, the modification module 6 may be advantageously configured to generate each of the modified event records by changing a monitored attribute of at least one variable of the respective monitored event record to the monitored attribute of that variable in another one of the monitored event records.

For instance, in the described example, the modification module 6 may generate a modified event record by changing an amount of rainfall in a first event record for an amount of rainfall recorded in a second event record.

In an example, the modification module 6 may be configured to only output modified event records to the selection module 8 that are considered feasible and/or sufficiently likely to occur.

For this purpose, the modification module 6 may be configured to generate each modified event record in the form of a modified pattern that is based on a respective one of the regular patterns, or a respective one of the irregular patterns, as described above.

In this manner, the modification module 6 may be configured to only output modified patterns having a weighted sum of pairwise distance (according to some distance metric) to the original, i.e. the respective regular or irregular, pattern that is less than a threshold distance, as shall become clear in the following description.

For example, the modification module 6 may be configured to generate each modified pattern by changing the monitored attribute of at least one vertex of the original pattern to the monitored attribute in a corresponding vertex of another regular or irregular pattern.

It shall be appreciated that this corresponds to changing the monitored attribute of at least one variable of an original event record to the monitored attribute of that variable in another monitored event record

In an example, the modification module 6 may generate at least one modified pattern by changing at least one of the expected attributes of an irregular pattern to the expected attribute of those variables in another pattern.

In an example, the modification module 6 may generate at least one modified pattern by changing at least one of the expected attributes of an irregular pattern to an anomalous attribute of those variables in another pattern.

In other examples, the modification module 6 may not change an expected attribute of an irregular pattern to an anomalous attribute because such a combination of monitored attributes may be considered not feasible or too unlikely to occur.

In an example, the modification module 6 may generate at least one modified pattern by changing at least one expected attribute of a regular pattern to another expected attribute or to an anomalous attribute for those variables in another pattern, for example.

The modification module 6 may also be configured to determine, or otherwise re-determine, the distances of the pairwise connections between the connected vertices of the modified pattern. In other words, the modification module 6 may re-determine the distances of the pairwise connection between the changed vertex and each of the connected vertices of the modified pattern.

The weighted sum of pairwise distance between the modified pattern and the original pattern may take the form of the difference between a weighted total of the pairwise distances of the modified pattern and a weighted total of the pairwise distances of the original pattern.

Hence, to ensure that only those modified patterns that are sufficiently likely to occur are output to the selection module 8, the modification module 6 may be configured to only output modified patterns having a weighted sum of pairwise distance to the original pattern that is less than the threshold distance.

In an example, the modification module may further include a filtering module 16 configured to select a set of the modified patterns to output to the selection module 8 that satisfy this condition.

The filtering module 16 may be configured to determine the weighted sum of pairwise distance between each modified pattern and the respective original pattern. Respective weights for each of the pairwise connections between the vertices of each pattern may be stored in a memory storage device of the filtering module 16, for example.

On this basis, the filtering module 16 may select those modified patterns, for which the weighted sum of pairwise distance to the respective original pattern is less than the threshold distance and the selected modified patterns may form the set of modified patterns that are output to the selection module 8.

To give some context to this, with reference to the example system of airports described above, the filtering module 16 may be configured to only output a modified pattern that was generated by changing the identification of the monitored airport from the first airport in the original pattern to the second airport in the modified pattern, if the first and second airports are sufficiently similar (e.g., in terms of size and weather/climate) so that the weighted sum of pairwise distance is less than the threshold distance.

It shall be appreciated that having similar attributes reduces the pairwise distance between the original pattern and the modified pattern.

In this manner, determining the weighted sum of pairwise distance for each modified pattern and comparing that distance to the threshold distance provides a binary classifier (within threshold or outside of threshold).

In an example, the filtering module 16 may be tuned with active learning to determine a suitable distance threshold. In active learning, expert-user input (i.e. the classification to some sample data) is used to improve the accuracy of the filtering module 16. In an example, active learning may select the samples in such a way that the impact of learning is maximised, whilst limiting the user input.

The selection module 8 is configured to receive and merge the one or more extracted exceptional event records and the one or more modified event records into a single set of event records. It shall be appreciated that, in an example, the one or more extracted exceptional event records may be received in the form of one or more irregular patterns and the one or more modified event records may be received in the form of one or more modified patterns.

On this basis, the selection module 8 is further configured to filter the set of event records into a subset of contingency event records that are output to the forecast simulation module 10.

For this purpose, the selection module 8 may be configured to rank the combined exceptional and modified event records based on one or more risk factors for each event record.

The one or more risk factors may include the likelihood of occurrence of the monitored attributes of that event record, and/or an impact score that is indicative of the relative impact of the monitored attributes of that event record on the operation of the monitored system.

For example, the selection module 8 may be configured to determine the likelihood of occurrence and an importance score for each of the modified patterns and the irregular patterns. The importance score and the likelihood of occurrence can each be determined based on respective algorithms that make use of the monitored attributes and the pairwise distances between the monitored attributes of each pattern.

For example, a modified pattern may include monitored attributes describing 30 cm of snowfall at the first airport and the modified pattern may therefore be considered relatively unlikely to occur (since such conditions would be anomalous).

Accordingly, the selection module 8 may be configured to quantify the likelihood of occurrence using a respective algorithm that identifies one or more comparable patterns that each include monitored attributes describing a similar amount of snowfall at a respective airport. Using this information, the algorithm may determine the likelihood of occurrence of the modified pattern, for example by assessing the frequency of occurrence of such snowfall in the patterns and/or by assessing the similarity of each airport to the first airport. By way of example, the similarity between a particular airport and the first airport may be determined by comparing one or more monitored attributes of the two airports, including a geographical location and/or average weather conditions amongst other relevant attributes.

The selection module 8 may determine the importance score of the modified pattern, in a substantially similar manner. For example, the selection module 8 may use a respective algorithm that effectively makes use of the measured impact of the snowfall on the performance measurements at each of the airports in the comparable patterns. Using this information, the algorithm may estimate the impact of the snowfall on the first airport by further assessing the similarity of each airport, in the comparable patterns, to the first airport and deciding whether similar effects should be expected or not on that basis. For example, the similarity may be determined by comparing one or more monitored attributes including the number of aircraft arriving at and/or departing from said airport amongst other relevant attributes.

It shall be appreciated that the selection module 8 and, in particular, the method of determining the importance score and/or the likelihood of future occurrence may be tuned with active learning.

In an example, the selection module 8 may be advantageously configured to rank the patterns based on the risk factors using a ranking function and to output the highest-ranking patterns to the forecast simulation module 10 as a subset of contingency patterns. The patterns may be ranked based on a weighted sum of the risk factors for each pattern, for example.

In an example, the selection module 8 may be configured to receive a threshold value of the weighted sum of the risk factors and to filter the ranked patterns by comparing the weighted sum of the risk factors of each pattern to the threshold value.

The threshold value may be determined so as to balance a trade-off between the size of the subset of contingency patterns after filtering, and the coverage gained by outputting the subset of contingency patterns to the forecast simulation module 10.

In another example, the selection module 8 may be configured to select the subset of contingency records by ranking the patterns according to a ranking function based on the weighted sum of the respective risk factors, determining the cumulative weighted sum of the respective risk factors of the highest ranking patterns and selecting those patterns for which the cumulative weighted sum Is less than or equal to a threshold value.

In this manner, the contingency forecasting system 1 is configured to advantageously balance the breadth of coverage of the contingency forecast simulation with the computational requirements of processing the subset of contingency patterns.

The forecast simulation module 10 is configured to generate one or more output parameters as the contingency forecast simulation. For this purpose the forecast simulation module 10 may apply one or more forecasting techniques to the selected subset of contingency event records, which may be received in the form of patterns, to determine a risk awareness snapshot.

Suitable forecasting techniques are well-known in the art and are not described in detail here to avoid obscuring the disclosure. Nonetheless, it shall be appreciated that a risk awareness snapshot, or a future event prediction, of the forecasting system can be used to identify or otherwise determine vulnerable areas of the monitored system to allow refinements that mitigate the effects of the possible events on the operation of the monitored system.

With reference to the example system of airports described above, the one or more output parameters may include one or more performance measurement estimates, for example predicting that a time between successive take offs/landings may increase by X amount if it snows at a particular airport.

Based on such information, the robustness of the monitored system of airports could be improved by identifying suitable airports for redirecting air traffic during such an event so that air traffic could be properly controlled to meet the reduced capacity of that airport.

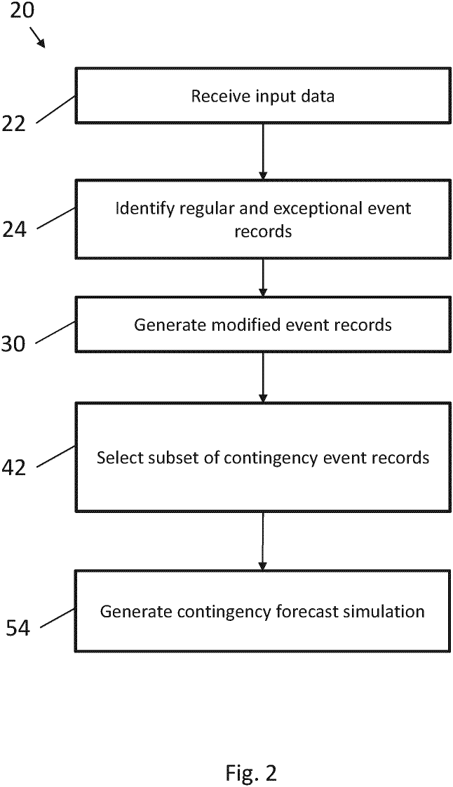

The operation of the contingency forecasting system 1 shall now be described with additional reference to FIGS. 2 to 5.

FIG. 2 shows an example method 20 of generating the contingency forecast simulation of a monitored system in accordance with an embodiment of the disclosure.

In step 22, the contingency forecasting system 1 includes the plurality of monitored event records, each describing the state of the monitored system during a respective event, or scenario, during which the monitored system was monitored.

For example, the plurality of monitored event records may be received at and/or stored in the input module 2, having been determined by one or more computing devices or sensor systems configured to observe the monitored system. The input module 2 may output the plurality of monitored event records to the extraction module 4, in step 22.

In step 24, the contingency forecasting system 1 determines one or more regular event records and one or more exceptional event records based on the plurality of monitored event records.

The contingency forecasting system may also determine a regular pattern for each of the regular event records and an irregular pattern for each of the exceptional event records.

For example, the extraction module 4 may receive the plurality of monitored event records, identify the exceptional event records and the regular event records, and pattern mine the exceptional event records separately from the regular event records in order to determine the respective irregular patterns and regular patterns.

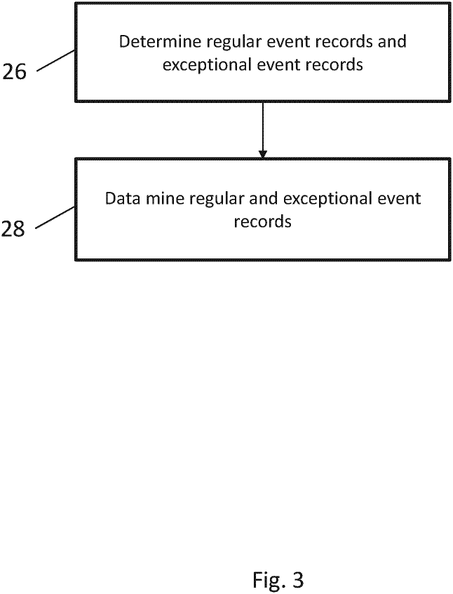

For this purpose, the method 20 may further include sub-steps 26 and 28, as shown in FIG. 3, which will now be described in more detail.

In sub-step 26, the extraction module 4 extracts, or identifies, one or more exceptional event records that include a threshold amount of anomalous attributes. The extraction module 4 also identifies one or more regular event records that do not include anomalous attributes, or otherwise include less than the threshold amount of anomalous attributes.

In an example, the anomaly detection module 12 may receive the plurality of monitored event records and apply one or more anomaly detection techniques to the monitored attributes of each monitored event record to identify the regular event records and the exceptional event records. In doing so, the anomaly detection techniques may determine a set of expected attributes and a set of anomalous attributes, for example.

Anomaly detection techniques are well-known in the art for this purpose and the anomaly detection module 12 may use a clustering method and/or an occurrence count, for example, to identify the regular event records and the exceptional event records. Such anomaly detection techniques are not described in detail here to avoid obscuring the disclosure.

In sub-step 28, the extraction module 4, and the pattern mining module 14 in particular, may determine the regular patterns by pattern mining the one or more regular event records. The pattern mining module 14 may also determine the irregular patterns by pattern mining the one or more exceptional event records.

Pattern mining methods are well-known in the art for this purpose, and the pattern mining module 14 may apply a Frequent Pattern Mining technique, an Apriori algorithm and/or an Eclat algorithm, for example, to determine the respective regular patterns and irregular patterns. Such pattern mining methods are not described in detail here to avoid obscuring the disclosure.

At the end of sub-step 28, the extraction module 4 may output the one or more regular patterns and the one or more irregular patterns to the modification module 6.

Returning to the method 20 shown in FIG. 2, in step 30, the contingency forecasting system 1 generates the modified event records based on the regular event records and/or the exceptional event records determined in step 24.

In an advantageous example, the contingency forecasting system 1 may generate the modified event records in the form of modified patterns, in step 30, based on the regular patterns and/or the irregular patterns.

The modified patterns effectively provide new patterns, based on the existing patterns, to anticipate future events that are likely to affect the operation of the monitored systems.

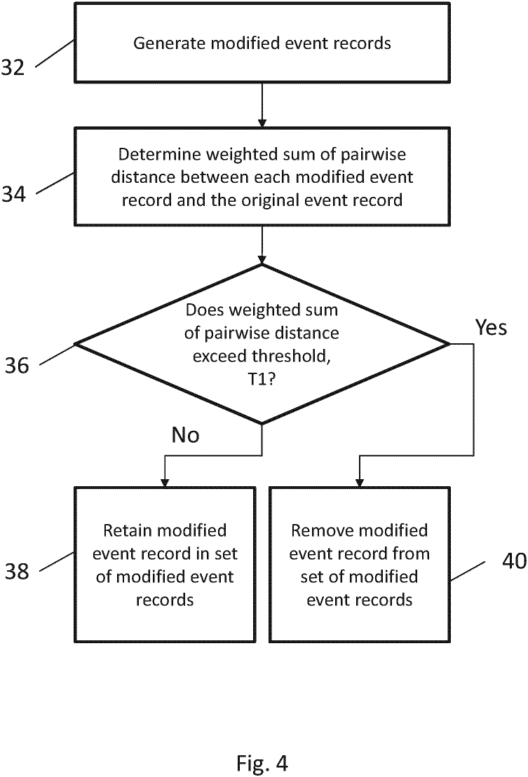

For this purpose, the method 20 may further include sub-steps 32 to 40, as shown in FIG. 4, which will now be described in more detail.

In sub-step 32, the modification module 6 may generate one or more modified patterns based on the one or more regular patterns and/or the one or more irregular patterns.

In particular, the modification module 6 may determine a plurality of modified patterns for each of the regular patterns and for each of the irregular patterns.

The modification module 6 may generate each modified pattern by modifying one or more monitored attributes of the respective regular pattern or the respective irregular pattern. For example, a modified pattern may be generated by changing a monitored attribute of the respective regular pattern to the monitored attribute of the same variable in another one of the regular or irregular patterns.

By way of example, a modified pattern may be generated by changing a first monitored attribute, such as a first amount of rainfall, in the respective regular pattern to a second monitored attribute, such as a second amount of rainfall, recorded in another pattern. In this manner, the modification module 6 combines the monitored attributes of different patterns to create modified patterns, whilst retaining a measure of the deviation from the original pattern by means of a change in pairwise distance.

In sub-step 34, the filtering module 16 determines, for each modified pattern, a weighted sum of pairwise distance between that modified pattern and the respective regular pattern or the respective irregular pattern that was modified to create that modified pattern, i.e. the original pattern.

It shall be appreciated that the weighted sum of pairwise distance between the modified pattern and the original pattern depends on the one or more monitored attributes that were changed. In particular, the weighted sum of pairwise distance may depend on the weighting of the changed attributes, and the distance of each change. In this regard, the weighting of the pairwise connection may represent the relative impact that different variables have on the operation of the monitored system. For example, the variable number of aircraft arriving at an airport may have a larger weighting than the variable number of luggage items passing through security at that airport. The distance of the change may represent a measure of the departure from the monitored attribute in the original pattern to the monitored attribute in the modified pattern. For example, increasing the number of aircraft arriving at an airport from 500 aircraft in the original pattern to 700 aircraft in a first modified pattern would have a larger pairwise distance than an increase from 500 aircraft in the original pattern to 600 aircraft in a second modified pattern.

Accordingly, the distance of each change may be based on the relative likelihood of occurrence of the respective monitored attributes in combination with the other monitored attributes of the pattern.

In sub-step 36, the filtering module 16 compares the weighted sum of pairwise distance associated with each modified pattern to the threshold distance.

The filtering module 16 retains those modified patterns, in sub-step 38, associated with a weighted sum of pairwise distance that is less than or equal to the threshold distance, forming the set of modified patterns that are output to the selection module 8.

Conversely, the filtering module 16 filters or removes, in sub-step 40, the remaining modified patterns, i.e. removing those modified patterns associated with a weighted sum of pairwise distance that exceeds the threshold distance from the set of modified patterns that are output to the selection module 8.

In step 42, the contingency forecasting system 1 selects the subset of contingency event records to output to the forecast simulation module 10 from a set of event records that include the modified event records and the exceptional event records.

In an advantageous example, the contingency forecasting system 1 may effectively select the subset of contingency event records to output based on the modified patterns output in step 30 and the irregular patterns determined in step 24.

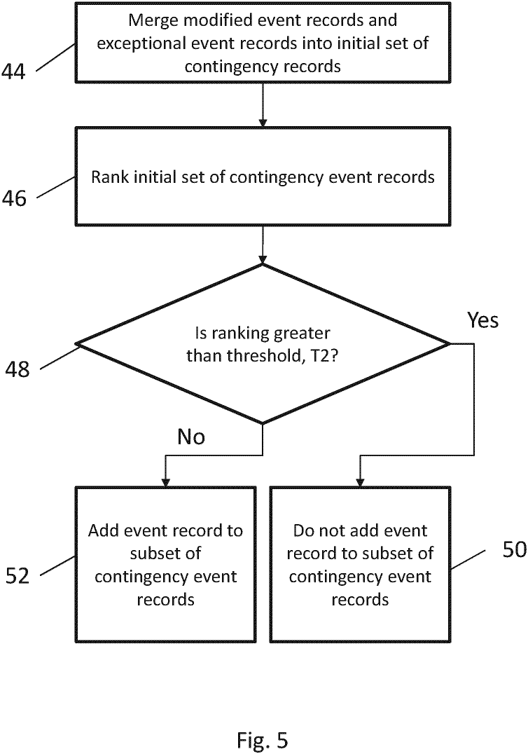

For this purpose, the method 20 may further include sub-steps 44 to 52, as shown in FIG. 5, which will now be described in more detail.

In sub-step 44, the selection module 8 receives the modified patterns output from the filtering module 16 and the one or more irregular patterns determined by the extraction module 4, and it merges the patterns into an initial set of contingency patterns.

In sub-step 46, the selection module 8 determines one or more risk factors for each pattern in the initial set of contingency patterns and ranks those patterns based on the risk factors.

Such risk factors may include an importance score for each pattern and an estimated frequency, or likelihood, of occurrence of each pattern.

In particular, the selection module 8 may determine the importance score of each pattern based on an importance score algorithm that is configured to estimate a measure of the relative impact of that pattern on the operation of the monitored system if that pattern were to occur. The algorithm used may be trained using active learning, for example.

The selection module 8 may determine the estimated frequency, or likelihood, of occurrence of each pattern based on a frequency algorithm configured to estimate the likelihood of occurrence of that pattern. For example, the frequency algorithm may be based at least in part on a cluster analysis, and/or on an occurrence count, of the monitored attributes of that pattern, within the plurality of monitored event records.

The selection module 8 may then determine a weighted sum of the importance score and the estimated frequency, or likelihood, of occurrence of each pattern. The weights of the sum may be provided by user inputs to the selection module 8 and/or trained using active learning.

The weighted sum of the importance score and the estimated frequency, or likelihood, of occurrence provides a numerical weighted sum value for each of the patterns in the initial set of contingency patterns, which may be used to rank the patterns in the initial set of contingency patterns.

In sub-step 48, the selection module 8 selects those patterns to output to the forecast simulation module 10, i.e. the subset of contingency patterns.

For this purpose, the selection module 8 may compare the weighted sum values of each of the patterns in the initial set of contingency patterns to a filtering threshold, which may be read from a memory storage device and/or computed by active learning.

The selection module 8 excludes those patterns associated with a weighted sum value that is less than the filtering threshold from the subset of contingency patterns, in sub-step 50. The excluded patterns correspond to possible events that are not considered sufficiently important and/or likely to occur to justify the computational requirements of performing contingency forecasting simulation on a data set including those removed patterns.

The selection module 8 selects those patterns associated with a weighted sum value that exceeds the filtering threshold to form part of the subset of contingency patterns that are output to the forecast simulation module 10 in sub-step 52. The subset of contingency patterns corresponds to possible events that are considered sufficiently important and/or likely to occur such that contingency forecasting simulation based on these patterns is justified.

In this manner, the method 20 balances a trade-off between the size of the subset of contingency patterns after filtering, and the coverage gained by outputting the subset of contingency patterns to the forecast simulation module 10.

In step 54, the forecast simulation module 10 generates one or more output parameters as the contingency forecast simulation by applying one or more forecasting techniques to the subset of contingency event records or patterns. In this example, the forecast simulation module 10 forms a risk awareness snapshot, which may include an event prediction, related to the operation of the monitored system based on the subset of contingency patterns or event records.

It may be possible to refine the monitored system, based on the risk awareness snapshot, to mitigate the effects of the possible events, corresponding to such patterns, on the operation of the monitored system if they occur in the future.

For example, the one or more output parameters may include one or more estimates of the performance of each airport during each of the events described by the subset of contingency event records and an estimated frequency of occurrence of each event. The estimates of the performance of a given airport may indicate that the time taken between successive take offs/landings may increase by 60 minutes if it snows at a particular airport.

Based on such information, the robustness of the monitored system of airports could be improved by identifying the second or third airport as a suitable airport for redirecting air traffic during such an event. In this manner, air traffic could be properly controlled to meet the reduced capacity of that airport, improving the robustness of the monitored system.

Many modifications may be made to the above-described example without departing from the scope of the appended claims.

In an example, the modification module 6 may be configured to only generate modified event records, or patterns, for which the weighted sum of the pairwise distances to the original event record, or pattern, is less than the threshold distance. For example, the modification module 6 may be configured to only change the monitored attributes of one or more variables of the original pattern, or event record, to the extent that the weighted sum of the pairwise distances (caused by the changes) remain less than the threshold distance. In this manner, there may be no need to filter the modified patterns, or event records, that are generated before they are output to the selection module 8.

In another example, the modification module 6 may be configured to output all of the modified event records, or patterns, that are generated to the selection module 8. In this example, the selection module 8 may have a larger processing requirement to ensure that the subset of contingency patterns corresponds to possible events that are considered sufficiently important and/or likely to occur such that contingency forecasting simulation based on these patterns is justified.

In another example, the contingency forecasting system may not include the above-described selection module, and the forecast simulation module may receive all of the modified patterns, or event records, generated by the modification module and/or all of the exceptional event records, which may be in the form of irregular patterns, from the extraction module. In such an example, the forecast simulation module may determine the contingency forecast simulation for each of the event records or patterns received. This may provide a much broader risk awareness snapshot with a greater computational requirement.

1. A contingency forecasting system for generating a contingency forecast simulation of a monitored system, the contingency forecast system comprising one or more computer processors configured to implement:
an input module configured to receive a plurality of monitored event records each describing a state of the monitored system during a monitored event of the monitored system, each monitored event record comprising a monitored attribute for each of a plurality of variables of the monitored system;
an extraction module configured to extract one or more of the plurality of monitored event records as exceptional event records in dependence on a determination of whether the monitored values satisfy respective regularity conditions;
a modification module configured to generate one or more modified event records, each modified event record being generated by modifying the monitored attribute of at least one of the variables of one of the monitored event records;
a selection module configured to select a subset of contingency event records from a set of event records comprising the extracted exceptional event records and the generated modified event records; and,
a forecast simulation module configured to apply one or more forecasting techniques to the selected subset of contingency event records to generate one or more output parameters as the contingency forecast simulation.

2. A contingency forecasting system according to claim 1, wherein the extraction module is configured to extract the exceptional event records by applying one or more anomaly detection techniques to the monitored attributes of each monitored event record.

3. A contingency forecasting system according to claim 2, wherein the one or more anomaly detection techniques are selected from: an occurrence count of the monitored attributes; and/or cluster analysis of the monitored attributes.

4. A contingency forecasting system according to claim 1, wherein the modification module is configured to generate each modified event record by changing the monitored attribute of at least one variable of the respective monitored 5 event record to the monitored attribute of that variable in another one of the monitored event records.

5. A contingency forecasting system according to claim 1, wherein the selection module is configured to: estimate one or more risk factors for each event record in the set of event records; and select one or more of the extracted exceptional event records and the modified event records from the set of event records based on the estimated risk factors.

6. A contingency forecasting system according to claim 5, wherein the one or more risk factors include: a likelihood, or frequency, of occurrence of the monitored attributes of that event record; and/or an impact score that is indicative of the relative impact of the monitored attributes of that event record on the operation of the monitored system.

7. A contingency forecasting system according to claim 5, wherein the selection module is configured to select the subset of contingency event records based on a weighted sum of the risk factors for each of the event records in the set of event records.

8. A contingency forecasting system according to claim 7, wherein the selection module is configured to select the subset of contingency event records by comparing the weighted sum of the risk factors of each of the event records in the set of event records to a threshold value.

9. A contingency forecasting system according to claim 7, wherein the selection module is configured to select the subset of contingency event records by: ranking the set of event records based on the weighted sum of the respective risk factors for each of the event records in the set of event records; determining the cumulative weighted sum of the respective risk factors of the highest ranking event records in the set of event records; and selecting those event records from the set of event records for which the cumulative weighted sum is less than or equal to a threshold value.

10. A contingency forecasting system according to claim 1, wherein the extraction module is configured to extract one or more of the plurality of monitored event records as exceptional event records that include an anomalous monitored attribute and to extract one or more of the plurality of monitored event records as regular event records that do not include an anomalous monitored attribute.

11. A contingency forecasting system according to claim 10, wherein the extraction module is configured to determine an irregular pattern, for each exceptional event record, by pattern mining the one or more exceptional event records, and/or a regular pattern for each regular event record by pattern mining the one or more regular event records, and wherein the modification module is configured to generate the modified event records in the form of modified patterns, each modified pattern being generated by modifying at least one of the monitored attributes of a respective one of the irregular patterns, or of a respective one of the regular patterns.

12. A contingency forecasting system according to claim 11, wherein the extraction module is configured to determine the one or more irregular patterns and/or the one or more regular patterns using one or more pattern mining methods selected from: a frequent pattern mining technique; an Apriori algorithm; and/or an Eclat algorithm.

13. A contingency forecasting system according to claim 11, wherein each pattern comprises one or more of the monitored attributes of the respective event record and a value for a pairwise connection between each pair of monitored attributes in that pattern.

14. A contingency forecasting system according to claim 1, wherein the modification module is configured to generate each modified pattern by changing at least one of: a monitored attribute, which is not an anomalous monitored attribute, of a respective regular pattern to an anomalous monitored attribute for that variable in an exceptional event record; and a monitored attribute, which is not an anomalous monitored attribute, of a respective irregular pattern to another monitored attribute for that variable, which is not an anomalous monitored attribute, in a regular event record.

15. A contingency forecasting system according to claim 11, wherein the modification module is configured to output modified patterns to the selection module, each modified pattern that is output to the selection module having a weighted sum of pairwise distance to the respective irregular pattern, or the respective regular pattern, that is less than a threshold distance.

16. A contingency forecasting system according to claim 15, wherein the modification module is configured to select a set of modified patterns from the generated modified patterns to output to the selection module by: determining a weighted sum of pairwise distances between each modified pattern generated and the respective irregular pattern, or the respective regular pattern; and selecting the modified patterns having a weighted sum of pairwise distances that is less than the threshold distance.

17. A contingency forecasting system according to claim 11, wherein each exceptional event record in the subset of contingency event records takes the form of a respective one of the irregular patterns and each modified event record in the subset of contingency event records takes the form of a respective one of the modified patterns, the selection module being configured to select the subset of contingency event records from the one or more irregular patterns and the one or more modified patterns.

18. A computer-implemented method of generating a contingency forecast simulation of a monitored system, the method comprising:
receiving a plurality of monitored event records each describing a state of the monitored system during a monitored event of the monitored system, each monitored event record comprising a monitored attribute for each of a plurality of variables of the monitored system; extracting one or more of the plurality of monitored event records as exceptional 5 event records in dependence on a determination of whether the monitored values satisfy respective regularity conditions;
generating one or more modified event records, each modified event record being generated by modifying the monitored attribute of at least one of the variables of one of the monitored event records;
selecting a subset of contingency event records from a set of event records comprising the extracted exceptional event records and the generated modified event records; and, generating one or more output parameters as the contingency forecast simulation by applying one or more forecasting techniques to the selected subset of contingency event records.

19. A non-transitory, computer-readable storage medium having instructions stored thereon that, when executed by a computer, cause the computer to carry out the method of claim 18.
